(19) United States
(12) Patent Application Publication
(10) Pub. No.: US 2024/0310161 A1
(43) Pub. Date: Sep. 19, 2024

(54) APPARATUS, SYSTEM, AND METHOD FOR ANALYZING THIN FILMS WITH IMPROVED PRECISION

(71) Applicant: AUROS Technology, Inc., Hwaseong-si (KR)

(72) Inventors: Tae Dong KANG, Hwaseong-si (KR); In Hee JOH, Hwaseong-si (KR); Say Yeon JOUNG, Hwaseong-si (KR); Moon Il SHIN, Hwaseong-si (KR)

(21) Appl. No.: 18/604,439

(22) Filed: Mar. 13, 2024

(30) Foreign Application Priority Data
Mar. 17, 2023 (KR) 10-2023-0034973

(51) Int. Cl. G01B 11/06; G01N 21/25; G06F 30/27

(52) U.S. Cl. CPC G01B 11/06; G01N 21/25; G06F 30/27; G01N 2201/121; G01N 2201/126

(57) ABSTRACT

An analyzing apparatus is provided. The analyzing apparatus may include a spectrum unit acquiring a spectrum related to semiconductor characteristics, and a corrector provided with a model that corrects at least one of noise and uncertainty of a measurement parameter related to the spectrum. The analyzing apparatus may include an evaluator provided to evaluate the uncertainty of the parameter corresponding to a controllable factor of measurement equipment that outputs the spectrum, and an attenuator provided to attenuate the spectral noise on the basis of an uncontrollable factor of the measurement equipment.

### CROSS-REFERENCE TO RELATED APPLICATION

This application claims priority to and the benefit of Korean Patent Application No. 10-2023-0034973 filed in the Korean Intellectual Property Office on Mar. 17, 2023, the entire contents of which are incorporated herein by reference.

### BACKGROUND

### Field

The present disclosure relates to an apparatus, system, and method for measuring and analyzing the characteristics of thin films of a semiconductor.

### Related Art

When it is desired to optically measure a thickness or an Optical Critical Dimension (OCD) in a semiconductor manufacturing process, a method of performing regression analysis by comparing a measurement spectrum and a theoretically calculated spectrum may be used.

However, the measurement spectrum has its own noise, and a regression analysis model is also affected by that noise.

### SUMMARY

In view of the above, the present disclosure provides an analysis apparatus, system, and method that can improve the measurement precision of thin films by creating an improved regression analysis model considering the effects of uncertain noises generated in measurement equipment, and lowering noises on a spectrum.

According to embodiments of the present disclosure, an analyzing apparatus may include a spectrum assembly, which includes measurement equipment, to acquire a spectrum, which represents one or more measured semiconductor characteristics, and a corrector provided with a model that corrects at least one of spectral noise and uncertainty of a measurement parameter of the spectrum.

According to embodiments of the present disclosure, an analyzing system may include a measuring apparatus to measure the one or more semiconductor characteristics and to output the spectrum that represents the one or more measured semiconductor characteristics, and the analyzing apparatus to receive the spectrum to correct at least one of the spectral noise and the uncertainty of the measured parameter of the spectrum.

According to embodiments of the present disclosure, an analyzing method may include acquiring a spectrum related to one or more semiconductor characteristics, evaluating uncertainty of a measurement parameter related to the spectrum, attenuating noise related to the spectrum, and generating a model to correct at least one of the noise and the uncertainty of the parameter.

According to embodiments of the present disclosure, an analyzing method may include acquiring a spectrum including measuring a thin film thickness of a semiconductor; evaluating uncertainty of a measurement parameter of the spectrum; attenuating spectral noise related to the spectrum; generating a model to correct at least one of the spectral noise and the uncertainty of the measurement parameter; and correcting the at least one of the spectral noise and the uncertainty of the measurement parameter.

An analyzing apparatus of the present disclosure can increase the precision of a measurement value by reducing the influence of noise when determining a parameter.

Thus, when it is desired to obtain a semiconductor thin film thickness or an OCD parameter using spectral measurement, the uncertainty of parameter analysis is reduced, so that the precision of measurement can be improved.

According to the present disclosure, when analyzing a spectrum, the precision of parameters can be improved by reducing noise or utilizing an improved regression analysis model to reduce the influence of noise.

According to the present disclosure, for a spectrum measured by measurement equipment, noise can be reduced using machine learning or the like, and simultaneously, the uncertainty of parameter data values expected from a physical model can be evaluated. Thereby, an optimization algorithm parameter can be supplemented, and measurement precision can be improved.

### BRIEF DESCRIPTION OF THE DRAWINGS

FIG. 1 is a schematic view showing an analyzing system according to an embodiment of the present disclosure.

FIG. 2 is a flowchart showing the operation of an evaluator according to an embodiment of the present disclosure.

FIG. 3 is a flowchart showing the operation of an attenuator according to an embodiment of the present disclosure.

FIG. 4 is a schematic view showing a spectrum according to an embodiment of the present disclosure.

FIG. 5 is a flowchart showing an analyzing method according to an embodiment of the present disclosure.

FIG. 6 is a diagram showing a computing device according to an embodiment of the present disclosure.

### DESCRIPTION OF EXEMPLARY EMBODIMENTS

Embodiments of the present disclosure will be described in detail with reference to the accompanying drawings such that those skilled in the art can easily practice the present disclosure. However, the present disclosure may be implemented in various ways without being limited to particular embodiments described herein. In order to clearly explain the present disclosure, parts that are not related to the description will be omitted. Like reference numerals refer to like parts throughout various figures and embodiments of the present disclosure.

In this specification, duplicate description of the same components will be omitted.

It will be understood that when a component is referred to as being “coupled” or “connected” to another component, it can be directly coupled or connected to the other component or intervening components may be present therebetween. In contrast, it should be understood that when a component is referred to as being “directly coupled” or “directly connected” to another component, there are no intervening components present.

The terminology used herein is for the purpose of describing particular embodiments only and is not intended to be limiting.

In the present disclosure, the singular forms are intended to include the plural forms as well, unless the context clearly indicates otherwise.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

In this specification, the term “and/or” includes a combination of multiple listed items or any of the multiple listed items. In this specification, “A or B” may include “A”, “B”, or “both A and B”.

Further, in this specification, detailed description of known functions and configurations that may obscure the gist of the present disclosure will be omitted.

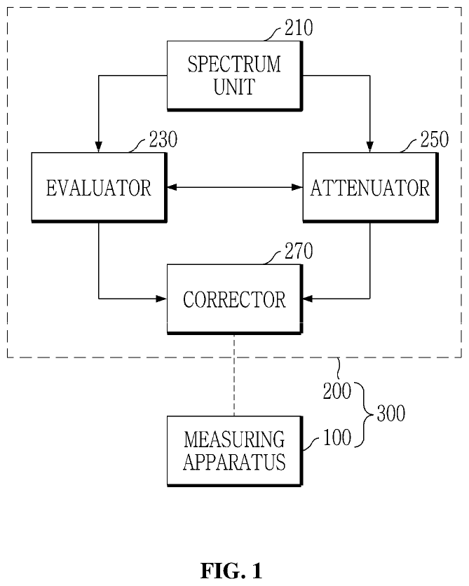

FIG. 1 is a schematic view showing an analyzing system 300 according to an embodiment of the present disclosure.

The analyzing system 300 shown in FIG. 1 may include a measuring apparatus 100 and an analyzing apparatus 200.

The measuring apparatus 100 may measure various characteristics such as the thickness of a thin film. As an example, the measuring apparatus 100 may measure one or more semiconductor characteristics and output a spectrum (measurement spectrum) indicating the measured characteristics.

The measuring apparatus 100 may perform a measurement process.

The measurement process may formalize a measurement model that attempts to predict a measured optical signal on the basis of an interaction model between a specific measuring system and a measurement target.

The measurement model may include the parametrization of a structure in terms of the physical properties of the measurement target (e.g. film thickness, critical dimension, refractive index, lattice pitch, etc.).

Further, the measurement model may include the parametrization (e.g. wavelength, incidence angle, polarization angle, etc.) of a measurement tool itself. For example, the parameters of the measuring apparatus may be parameters used to characterize the measurement tool itself. Examples of the parameters of the measuring apparatus may include an angle of incidence (AOI), an analyzer angle (AO), a polarizer angle (PO), an illumination wavelength, a numerical aperture (NA), etc.

Sample parameters may be parameters used to characterize the geometric and material properties of a sample. For a thin-film sample, examples of the sample parameters may include a refractive index, a dielectric function tensor, nominal layer thickness of all layers, a layer sequence, etc.

The analyzing apparatus 200 may receive a measurement spectrum from the measuring apparatus 100 to attenuate noise or correct a physical model.

The analyzing apparatus 200 may include a spectrum unit (spectrum device or spectrum assembly) 210, an evaluator 230, an attenuator 250, and a corrector 270.

The spectrum unit 210 may acquire a spectrum indicating at least one of characteristics, such as the critical dimension, film thickness, composition of a nanoscale structure. As an example, optical equipment may be provided to radiate light toward a semiconductor or thin-film structure and generate a spectrum using the radiated light. The optical equipment may measure optical characteristics such as the thickness and refractive index of the thin film using the polarization characteristics of light. For example, the optical equipment may include a light source that provides an amount of illumination to a measurement point on a semiconductor wafer over a spectral range for the semiconductor wafer, and a spectrometer that collects an amount of light from the measurement point in response to the provided illumination and represents the spectral response of the semiconductor wafer at the measurement point.

At this time, the spectrum unit 210 may be provided with a communication module for wired or wireless communication with the optical equipment. In this case, the spectrum unit 210 may receive the spectrum from the optical equipment.

As another example, the spectrum unit 210 may include the optical equipment itself. In this case, the spectrum unit 210 may directly acquire the optical spectrum.

The optical equipment such as a Spectroscopic Ellipsometer (SE) and a Spectroscopic Reflectometer (SR) may measure thickness from a few nanometers to tens of millimeters.

The spectrum acquired through the spectrum unit 210 may contain some errors.

As an example, the noise of the measurement equipment may be included in the spectrum. Alternatively, noise caused by various environmental factors such as electromagnetic waves and magnetic fields around the measurement equipment may be included in the spectrum. As such, if various noises are included in the spectrum, the noises may affect a post-processing analysis, such as the regression analysis model that measures the thickness of the thin film on the basis of the spectrum. As a result, a result value output from the post-processing analysis may also contain some errors due to various noises included in the spectrum.

In order to improve the precision and accuracy of the spectrum and post-processing analysis, it is preferable to reduce noise included in the spectrum.

The corrector 270 may be provided with a model that corrects at least one of the noise and the uncertainty of the measurement parameter related to the spectrum. The model may be obtained from the evaluator 230 or the attenuator 250.

The measurement equipment's own noise may be based on uncertainty in the measurement parameters, which are controllable factors. For example, various parameters of the measurement equipment may be set during the initial setting process or tuning process of the measurement equipment. Taking a spectroscopic elliptical optical system as an example, examples of the parameters may include an angle of incidence (AOI), an analyzer angle (AO), a polarizer angle (PO), an illumination wavelength, a numerical aperture (NA), etc. At this time, the uncertainty of the spectrum output from the measurement equipment may vary depending on the stability of specific parameters.

The term “uncertainty” may indicate how much or how often the output value output each time is not fixed and is output differently, in a state where a parameter set value is applied. The uncertainty may vary depending on the parameter set value. The lower uncertainty associated with the expectation that any value will be fixedly output when a certain value is input is preferable. This is because low uncertainty indicates that a second value is always output fixedly when a first value is input. In contrast, high uncertainty may indicate that when the first value is input, there is a high probability that values other than the second value will be output. Therefore, the low uncertainty has the same meaning as the high precision.

The evaluator 230 may evaluate the uncertainty of parameters corresponding to controllable factors of the measurement equipment that outputs the spectrum. The controllable factors may include or be related to initial setting parameters of the measuring equipment. The evaluator 230 may evaluate the uncertainty while changing parameters, and may evaluate the uncertainty as being low if the uncertainty is equal to or less than the first set value. The set value of the parameter evaluated as having low uncertainty may be applied to the measurement equipment or applied to the physical model of the measurement equipment. The first set value of uncertainty may be said to be precision expressed as a standard deviation value, taking a thickness value as an example. In other words, this may indicate that the thickness value which may be obtained during repeated measurement is set to be obtained as a probability distribution in the form of the Gaussian distribution function of this standard deviation.

$${P}_{m} = - \frac{1}{2 π {σ}_{m}^{2}} exp \{ - \frac{{( {t}_{m} - \overline{{t}_{m}} )}^{2}}{2 {σ}_{m}^{2}} \}$$

Here, m is a parameter index, Ò is the standard deviation of the parameter, and t is a parameter value such as the thickness value that is to be obtained through analysis.

In addition, there may be factors that are uncontrollable internally or externally to the measurement equipment, and noise may be included in the spectrum due to these factors. For example, the uncontrollable factors may include those depending on the physical properties of the measurement target (e.g. film thickness, critical dimension, refractive index, lattice pitch, etc.). Further, for the thin film sample, exemplary uncontrollable factors may relate to one or more of the refractive index, the dielectric function tensor, the nominal layer thickness of all layers, and a layer sequence. In other words, the uncontrollable factors may include the nominal layer thickness of all layers, the layer sequence, etc.

The attenuator 250 may attenuate spectral noise based on the uncontrollable factors of the measurement equipment. The noise may include irregular elements, and it may be actually difficult to attenuate the noise using the physical model. Mathematical processing such as an artificial intelligence model or smoothing may be used to actually attenuate noise.

The corrector 270 may generate a model on the basis of the evaluation result of the evaluator 230 and the attenuation result of the attenuator 250. The model generated by the corrector 270 may correct the uncertainty of the parameter or correct the noise.

For example, the corrector 270 may generate a first model and a second model.

The first model may include the physical model of the measurement equipment whose precision satisfies a first set value.

The corrector 270 may output a parameter applied to the first model, output a spectrum generated by the first model, or output the first model itself.

The second model may include a machine learning model or a mathematical processing method that attenuates noise to the extent that the standard deviation of the parameter value obtained and analyzed by attenuating noise becomes less than or equal to the second set value. Here, the second set value is a precision standard targeted in a precision test in the attenuator, and may be given as the value of the standard deviation of the parameter to be measured.

The corrector 270 may output a spectrum in which noise is attenuated by the second model, or output the second model itself. When the measurement equipment or the physical model that outputs the spectrum is provided, the second model may attenuate noise in the spectrum output from the measurement equipment or the physical model using the second model.

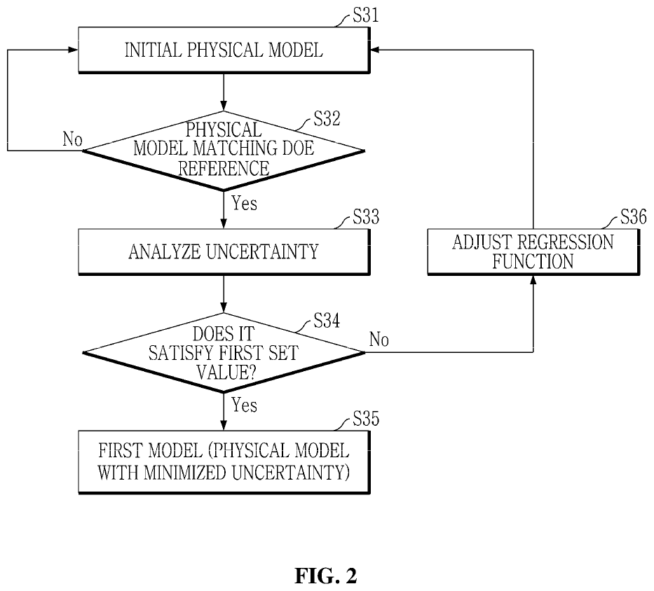

FIG. 2 is a flowchart showing the operation of the evaluator 230 according to an embodiment.

The evaluator 230 may extract one or more spectrum(s) of a Design Of Experiments (DOE) wafer and a physical model matching reference (DOE reference) values of their target parameters (S 31) (S 32).

In order to create a measurement solution, the DOE wafer may refer to a wafer(s) manufactured by experimentally planning to show the minimum and maximum values of a target parameter desired to be measured, which may occur during a normal process. The target parameter values obtained by measuring these wafers with reference equipment (e.g. a transmission electron microscope (TEM), etc.) are called DOE reference parameters. The model may be optimized so that the parameter values, obtained by analyzing the spectrum measured from the wafer(s) with the physical model, and reference parameter values match as much as possible.

The evaluator 230 may analyze the uncertainty of the extracted physical model (S 33). When analyzing the uncertainty, noise information in the measurement spectrum may be selectively used, so that the attenuator that optimizes the noise in the spectrum may contribute to the optimization of the first model that is optimized in the evaluator.

The evaluator 230 may extract the first model corresponding to the physical model whose analyzed uncertainty satisfies the target first set value (target uncertainty) (S 34).

The evaluator 230 may provide the first model to the corrector 270 (S 35) or evaluate the uncertainty of the parameter using the first model (S 33).

The evaluator 230 may adjust the regression function of the physical model when the uncertainty does not satisfy the first set value (S 36). For example, when the uncertainty does not satisfy the first set value, the evaluator 230 may select and adjust one or more of the type of spectrum, a wavelength range, spectrum or parameter weight, and parameters to be obtained through regression analysis in the regression analysis function. The first set value may include or be related to the precision expressed as the standard deviation value of the thin film thickness value.

The evaluator 230 may reanalyze the uncertainty when the unsatisfactory physical model matches the DOE reference.

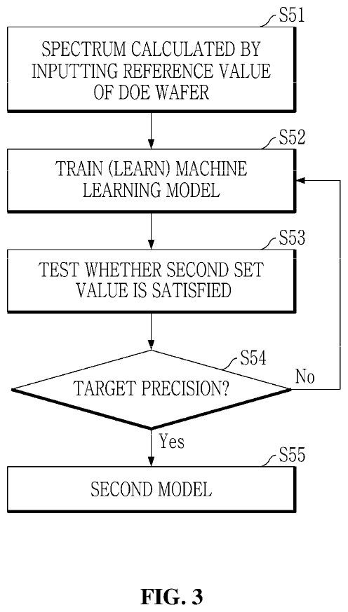

FIG. 3 is a flowchart showing the operation of the attenuator 250 according to an embodiemnt.

The attenuator 250 may train (learn) a machine learning model using a dataset that takes, as a question, the measurement spectrum obtained from DOE wafers and including noise, and has, as an answer, a spectrum calculated by inputting a reference value of the DOE wafer into the first model optimized by the evaluator (S 51) (S 52) (S 53) (S 54). The attenuator 250 receives the spectrum calculated by the first model and uses it as the correct answer for the dataset. In this machine learning process, when the spectrum (including noise) output from the measurement equipment is input, the noise-attenuated spectrum is output, and the noise-attenuated spectrum is tested using the first model. According to the test result, the machine learning model satisfying the target precision may be provided. The precision performance of the corresponding machine learning model may be improved depending on the amount of machine learning. By using this machine learning model, it is possible to obtain the function of determining whether there is an abnormality on the spectrum.

In the process of optimizing the machine learning model in the attenuator 250, it is possible to test whether a second set value of the parameter is satisfied by the amount of noise attenuation using a set of precision test spectra that are repeatedly measured under preset conditions (S 53). At this time, in order to increase data correlation with the physical model, the spectrum calculated from the model optimized by the evaluator 230 may be used.

In other words, the attenuator 250 may test whether the amount of noise attenuation satisfies the second set value using the preset spectrum. At this time, the preset spectrum may include the set of precision test spectra that are repeatedly measured under the preset conditions during the process of optimizing the machine learning model in the attenuator 250.

The attenuator 250 may provide the second model, corresponding to the machine learning model satisfying the second set value, to the corrector 270, or provide the noise-attenuated spectrum using the second model (S 54)(S 55).

The corrector 270 may provide at least one of the first model and the second model to a post-processing analayzer, or provide at least one of an output value of the first model and an output value of the second model to an acquirer that is the post-processing analyzer.

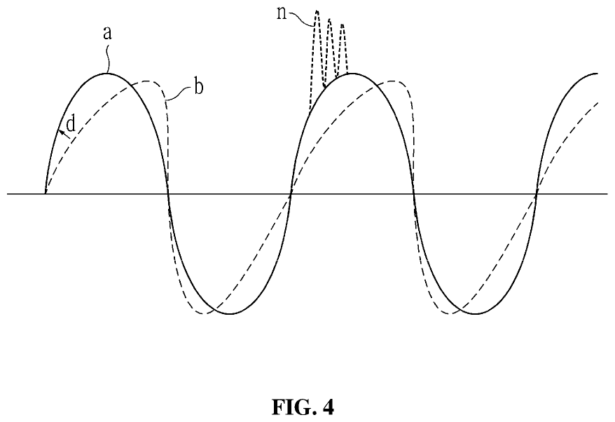

FIG. 4 is a schematic view showing the spectrum according to an embodiment.

As shown in FIG. 4, the corrector 270 may display the setting parameter of the first model with corrected uncertainty through a display or provide the first model to the measurement equipment. A user may adjust the first-model parameter of the measurement equipment according to the value indicated on the display. Alternatively, the measurement equipment may automatically apply the first-model parameter value that is provided from the corrector 270.

Further, as shown in FIG. 4, the corrector 270 may attenuate noise n included in the measurement spectrum. Thereby, the measurement spectrum may become a spectrum a that is optimized by the machine learning model to obtain optimal precision.

Turning back to FIG. 1, the post-processing analyzer may acquire the first model through the corrector, acquire the spectrum a optimized for precision rather than a measurement spectrum b, and perform various post-processes using them. Since post-processing is performed on the basis of the original spectrum a, the post-processing result of the post-processing analzyer may be close to an ideal value.

As an example, the post-processing analzyer may include a measuring apparatus 100 that measures the thin-film thickness.

The measuring apparatus 100 may acquire and analyze the spectrum measuring the semiconductor on which the thin film is formed. The spectrum obtained from the actual measurement equipment may include errors due to the above-described uncertainty of the parameter and noise due to various environments.

According to the present disclosure, the measuring apparatus 100 may receive the first model with improved uncertainty and the second model with improved spectrum noise from the corrector 270, and then perform the analysis of the measured spectrum.

For example, the measuring apparatus 100 may receive a physical model with improved uncertainty from the first model, and receive a spectrum on which correction has been completed from the second model.

The corrector 270 provided in the analyzing system 300 may remove spectrum noise from the spectrum acquired through the measuring apparatus 100 and determine whether there is abnormality in the spectrum, thus estimating the possibility of an abnormal thickness or predicting the location of an abnormal layer in the thin film structure.

The measuring apparatus 100 may measure the thickness of each of the plurality of thin films forming the thin film structure by analyzing the spectrum. At this time, the thickness of the thin film may be within the range of 1 Å to 500 μm.

In the case of using an actual measurement spectrum that includes errors and noise due to the parameter with uncertainty, if it does not go through the corrector 270, the errors and noise still affect the precision of the prediction result and the measurement result in the measuring apparatus 100. However, according to the present disclosure, since the spectrum input through the measuring apparatus 100 is input into the measuring apparatus 100 with errors and noise excluded through the corrector 270, the accuracy and reliability of the measurement result can be guaranteed.

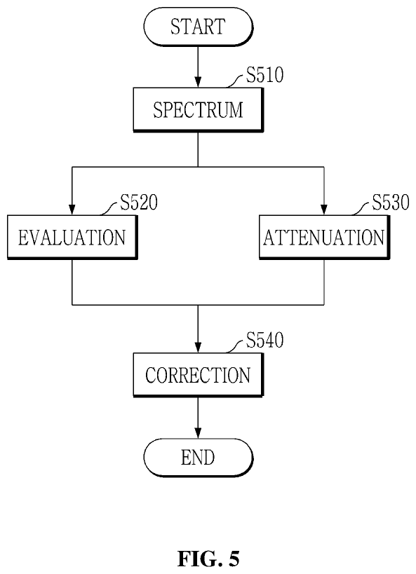

FIG. 5 is a flowchart showing an analyzing method according to an embodiment of the present disclosure.

The analyzing method of FIG. 5 may be performed by the analyzing system 300 or the analyzing apparatus 200 shown in FIG. 1.

The analyzing method may include a spectrum step S 510, an evaluation step S 520, an attenuation step S 530, and a correction step S 540.

The spectrum step S 510 may acquire the spectrum measuring the thin film thickness of the semiconductor. The spectrum step S 510 may be performed by the spectrum unit 210.

The evaluation step S 520 may evaluate the uncertainty of the measurement parameter related to the spectrum. The evaluation step S 520 may be performed by the evaluator 230. When evaluating the uncertainty, the noise information of the measurement spectrum may be selectively used. Thus, the attenuation step S 530 of optimizing the spectrum noise may contribute to the optimization of the first model performed in the evaluation step S 520.

The attenuation step S 530 may attenuate noise related to the spectrum. The attenuation step S 530 may be performed by the attenuator 250. In order to increase data correlation with the physical model, the spectrum calculated from the first model optimized in the evaluation step S 520 may be used to attenuate noise in the attenuation step S 530. The correction step S 540 may generate the model that corrects at least one of the noise and uncertainty of the parameter. The correction step S 540 may be performed by the corrector 270.

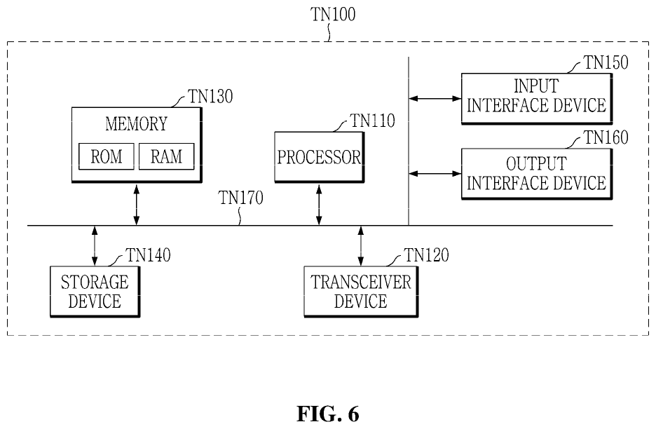

FIG. 6 is a diagram showing a computing device according to an embodiment of the present disclosure. The computing device TN100 of FIG. 6 may be an apparatus (e.g. one or more of the analyzing system 300, the analyzing apparatus 200, the measuring apparatus, etc.) described herein.

In the embodiment of FIG. 6, the computing device TN100 may include at least one processor TN110, a transceiver device TN120, and at least one memory TN130. The computing device TN100 may further include a storage device TN140, an input interface device TN150, an output interface device TN160, etc. Components included in the computing device TN100 may be connected by a bus TN170 to communicate with each other.

The processor TN110 may execute a program command stored in at least one of the memory TN130 and the storage device TN140. The processor TN110 may refer to a central processing unit (CPU), a graphics processing unit (GPU), or a dedicated processor in which methods according to an embodiment of the present disclosure are performed. The processor TN110 may be configured to implement a procedure, a function, and a method described in connection with the embodiment of the present disclosure. The processor TN110 may control each component of the computing device TN100.

Each of the memory TN130 and the storage device TN140 may store various pieces of information related to the operation of the processor TN110. Each of the memory TN130 and the storage device TN140 may include at least one of a volatile storage medium and a non-volatile storage medium. For example, the memory TN130 may include at least one of a read only memory (ROM) and a random access memory (RAM).

The transceiver device TN120 may transmit or receive a wired signal or a wireless signal. The transceiver device TN120 may be connected to a network to perform communication.

Meanwhile, the embodiment of the present disclosure is not only implemented through the apparatus and/or method described so far, but may also be implemented through a program that realizes a function corresponding to the configuration of the embodiment of the present disclosure or a recording medium in which the program is recorded. This implementation can be easily implemented by those skilled in the art from the description of the above-described embodiment.

Although embodiments of the present disclosure have been described in detail, the scope of the present disclosure is not limited thereto and various modifications and improvements made by those skilled in the art using the basic concept of the present disclosure as defined in the following claims also fall within the scope of the present disclosure.

Description of Reference Numerals

| | | | |
|---|---|---|---|
| 100 | measuring apparatus | 200 | analyzing apparatus |
| 210 | spectrum unit | 230 | evaluator |
| 250 | attenuator | 270 | corrector |
| 300 | analyzing system | | |

What is claimed is:

1. An analyzing apparatus comprising:
a spectrum assembly, which includes measurement equipment, to acquire a spectrum which represents one or more measureed semiconductor characteristics; and
a corrector provided with a model that corrects at least one of spectral noise and uncertainty of a measurement parameter of the spectrum.

2. The analyzing apparatus of claim 1, further comprising:
an evaluator provided to evaluate the uncertainty of the parameter corresponding to a controllable factor of the measurement equipment that outputs the spectrum; and
an attenuator provided to attenuate the spectral noise based on an uncontrollable factor of the measurement equipment,
wherein the corrector generates the model based on an evaluation result of the evaluator and an attenuation result of the attenuator.

3. The analyzing apparatus of claim 2, wherein:
the controllable factor includes an initial setting parameter of the measurement equipment, and
the uncontrollable factor includes one or more of a film thickness of a measurement target, a critical dimension, a refractive index, a lattice pitch, a nominal layer thickness of a layer, and a layer sequence.

4. The analyzing apparatus of claim 1, wherein:
the corrector generates a first model and a second model,
the first model comprises a physical model of the measurement equipment whose uncertainty satisfies a first set value, and
the second model comprises a machine learning model that attenuates the spectral noise by a second set value.

5. The analyzing apparatus of claim 1, wherein the corrector generates a first model corresponding to a physical model of the measurement equipment whose uncertainty satisfies a first set value, and
the corrector outputs a parameter applied to the first model, outputs a first spectrum generated by the first model, or outputs the first model itself.

6. The analyzing apparatus of claim 4, wherein the first set value is a standard deviation value of a thin-film thickness value.

7. The analyzing apparatus of claim 1, wherein:
the corrector generates a second model corresponding to a machine learning model that attenuates the spectral noise by a second set value, and
the corrector outputs a second spectrum in which the spectral noise is attenuated by the second model, or outputs the second model itself.

8. The analyzing apparatus of claim 7, wherein, when the physical model or the measurement equipment outputting the spectrum is provided, the second model attenuates the spectral noise of the spectrum output from the measurement equipment or the physical model by the second set value.

9. The analyzing apparatus of claim 1, further comprising:
an evaluator provided to evaluate the uncertainty of the parameter corresponding to a controllable factor of the measurement equipment that outputs the spectrum, wherein:
the evaluator is provided to extract a physical model matching one or more spectra of a Design Of Experiments (DOE) wafer related to the spectrum and a reference of the parameter,
the evaluator analyzes uncertainty of the extracted physical model,
the evaluator extracts a first model corresponding to the physical model whose analyzed uncertainty satisfies a first set value, and
the evaluator provides the first model to the corrector, or evaluates the uncertainty of the parameter using the first model.

10. The analyzing apparatus of claim 9, wherein:
the evaluator adjusts a regression function of the physical model, when the uncertainty does not satisfy the first set value, and
the evaluator reanalyzes the uncertainty when the physical model that does not satisfy the first set value matches a DOE reference.

11. The analyzing apparatus of claim 10, wherein the regression function is adjusted by selecting and adjusting one or more of a type of spectrum, a wavelength range, a parameter weight, and parameters to be obtained through regression analysis.

12. The analyzing apparatus of claim 9, wherein the attenuator is provided to train the machine learning model using a dataset that takes, as a question, the spectrum obtained from the DOE wafer and including the spectral noise, and has, as an answer, a spectrum calculated by inputting a reference value of the DOE wafer into the first model optimized by the evaluator,
the attenuator tests whether an amount of spectral noise attenuation satisfies the second set value using a preset spectrum, and
the attenuator provides the second model, corresponding to the machine learning model satisfying the second set value, to the corrector, or attenuates the spectral noise using the second model.

13. The analyzing apparatus of claim 12, wherein the preset spectrum comprises a set of precision test spectra that are repeatedly measured under preset conditions during a process of optimizing the machine learning model in the attenuator.

14. An analyzing system comprising:
a measuring apparatus to measure one or more semiconductor characteristics and to output the spectrum that represents the measured one or more semiconductor characteristics; and
the analyzing apparatus of claim 1 to recieve the spectrum to correct at least one of the spectral noise and the uncertainty of the measured parameter of the spectrum.

15. An analyzing method performed by an analyzing apparatus, the analyzing method comprising:
acquiring a spectrum including meausring a thin film thickness of a semiconductor;
evaluating uncertainty of a measurement parameter related to the spectrum;
attenuating spectral noise related to the spectrum;
generating a model to correct at least one ofthe spectral noise and the uncertainty of the measurement parameter;
correcting the at least one of the spectral noise and the uncertainty of the measurement parameter; and
outputting an updated spectrum based on the correction of the at least one of the spectral noise and the uncertainty of the measurement parameter.

16. The analyzing apparatus of claim 5, wherein the first set value is a standard deviation value of a thin-film thickness value.
